(19) United States
(12) Patent Application Publication
(10) Pub. No.: US 2024/0048107 A1
(43) Pub. Date: Feb. 8, 2024

(54) OUTPUT MATCHING NETWORK WITH IMPROVED WIDE BAND CHARACTERISTICS AND POWER AMPLIFIER NETWORK INCLUDING THE SAME

(71) Applicant: SAMSUNG ELECTRONICS CO., LTD., SUWON-SI (KR)

(72) Inventors: Kyutaek Oh, Busan (KR); Ockgoo Lee, Busan (KR); HYUNCHUL PARK, Suwon-si (KR); Hyunjin Ahn, Busan (KR); Sangmin Yoo, Suwon-si (KR); Jaeyeon Jeong, Suwon-si (KR); Joonhoi Hur, Suwon-si (KR)

(73) Assignees: Samsung Electronics Co., Ltd., SUWON-SI (KR); Pusan National University Industry-University Cooperation Foundation, Busan (KR)

(21) Appl. No.: 18/364,763

(22) Filed: Aug. 3, 2023

(30) Foreign Application Priority Data
Aug. 5, 2022 (KR) 10-2022-0098164
Nov. 21, 2022 (KR) 10-2022-0156087

(51) Int. Cl. H03F 3/24; H03F 1/56; H04B 1/04

(52) U.S. Cl. CPC H03F 3/245; H03F 1/56; H04B 1/0458; H03F 2200/09; H03F 2200/387; H04B 2001/0408

(57) ABSTRACT

Disclosed is an output matching network including a first transmission line and a second transmission line each having one end connected to a respective balanced port of a pair of balanced ports; a third transmission line having one end connected to an unbalanced port; and a fourth transmission line. A first capacitor is connected to the unbalanced port and a load. A second capacitor is connected to an end of the fourth transmission line. The third and fourth transmission lines are coupled to the first and second transmission lines.

### CROSS-REFERENCE TO RELATED APPLICATIONS

This application claims priority under 35 U.S.C. § 119 to Korean Patent Application No. 10-2022-0098164 filed on Aug. 5, 2022, and Korean Patent Application No. 10-2022-0156087 filed on Nov. 21, 2022 in the Korean Intellectual Property Office, the disclosures of which are incorporated by reference herein in their entireties.

### TECHNICAL FIELD

Embodiments of the present disclosure relate to an output matching network with improved wide band characteristics and a power amplifier network including the same.

### DISCUSSION OF RELATED ART

Various communication modules for supporting mmWave communication are being developed and researched. Maximum output power and power efficiency, which are key performance parameters of a power amplifier (PA) in front-end transmit circuitry may be influenced by an output matching network of the power amplifier. In particular, the maximum output power and maximum high power efficiency may be achieved when the output matching network provides the optimum impedance to the output device of the power amplifier. However, current output matching network technology for supporting various frequency bands in today's broadband (wide frequency range) microwave and millimeter wave communication requires additional components or circuits, which typically occupies a large area and suffers from high loss.

### SUMMARY

Embodiments of the present disclosure provide an output matching network with improved wide frequency band characteristics through a balun circuit configurable with transmission lines having shorter lengths relative to prior art designs, and a power amplifier network including the same.

According to an embodiment of the present disclosure, an output matching network includes a first transmission line and a second transmission line each having one end connected to a respective balanced port of a pair of balanced ports; a third transmission line having one end connected to an unbalanced port; and a fourth transmission line. A first capacitor is connected to the unbalanced port and a load. A second capacitor is connected to an end of the fourth transmission line. The third and fourth transmission lines are coupled to the first and second transmission lines.

In various embodiments:

The capacitance of the first capacitor may differ from the capacitance of the second capacitor.

Each of the first through fourth transmission lines may have an electrical length of 90 degrees or less.

The first and third transmission lines may be electromagnetically coupled to one another, and disposed parallel to each other in a horizontal or vertical direction, and the second and fourth transmission lines are electromagnetically coupled to one another and disposed parallel to each other in a horizontal or vertical direction.

The output matching network may further include a pair of input capacitors connected to the pair of balanced ports.

An odd-mode characteristic impedance and an even-mode characteristic impedance of each of the first through fourth transmission lines may be adjusted based on the first and second capacitors.

Another end of each of the first and second transmission lines may be grounded.

Another end of the first transmission line may be connected to another end of the second transmission line.

According to an embodiment of the present disclosure, a power amplifier network includes: a power amplifier configured to amplify an input signal to provide an amplified input signal including first and second differential signals, at first and second balanced ports, respectively; and an output matching network including: an unbalanced port at which an unbalanced output signal is output to a load; a balun circuit including a plurality of transmission lines that receive the first and second differential signals, wherein the balun circuit converts the first and second differential signals to the unbalanced output signal at the unbalanced port; a first capacitor connected to the unbalanced port; and a second capacitor connected between an end of one of the transmission lines and a point of reference potential (e.g., ground).

According to an embodiment of the present disclosure, a wireless communication device includes: a processor; an RF transceiver; front end circuitry; and an antenna. The front end circuitry includes: a power amplifier configured to amplify the RF signal to provide an amplified RF signal including first and second differential signals, at first and second balanced ports, respectively; and an output matching network including: an unbalanced port at which an unbalanced output signal is output to a load; a balun circuit including a plurality of transmission lines that receive the first and second differential signals, where the balun circuit converts the first and second differential signals to the unbalanced output signal at the unbalanced port; a first capacitor connected to the unbalanced port; and a second capacitor connected between an end of one of the transmission lines and a point of reference potential. The antenna is configured to transmit the unbalanced output signal.

### BRIEF DESCRIPTION OF THE FIGURES

A brief description of each drawing is provided to facilitate a more thorough understanding of the drawings referenced in the detailed description of the present disclosure.

FIG. 1 is a circuit diagram of an output matching network, according to an embodiment of the present disclosure.

FIG. 2A is a plan view of an edge-side type balun circuit, according to an embodiment of the present disclosure.

FIG. 2B is a side view of an area ‘A’ of a balun circuit of FIG. 2A.

FIG. 3 is a circuit diagram of a power amplifier network, according to an embodiment of the present disclosure.

FIG. 4 is a diagram illustrating an integrated circuit of a power amplifier network of FIG. 3.

FIG. 5 is a circuit diagram of a power amplifier network, according to another embodiment of the present disclosure.

FIG. 6 is a circuit diagram of an embodiment of a power amplifier network of FIG. 5.

FIG. 7A and 7B are circuit diagrams of a drive amplifier and a power amplifier of FIG. 6.

FIG. 8 illustrates a wireless communication device, according to an embodiment of the present disclosure.

FIG. 9 is a diagram illustrating an embodiment of a front end module (FEM) of FIG. 8.

FIG. 10 illustrates a wireless communication device, according to another embodiment of the present disclosure.

### DETAILED DESCRIPTION

Hereinafter, embodiments of the present disclosure may be described in detail and clearly to such an extent that one of ordinary skill in the art can readily implement these and other embodiments.

In the following description, after an element is first introduced by a name and a label, it may later be referred to by either a shortened version of the name and the label, or by just the label. For instance, a “first impedance matching capacitor CL1” may subsequently be referred to as just “capacitor CL1” or just “CL1”.

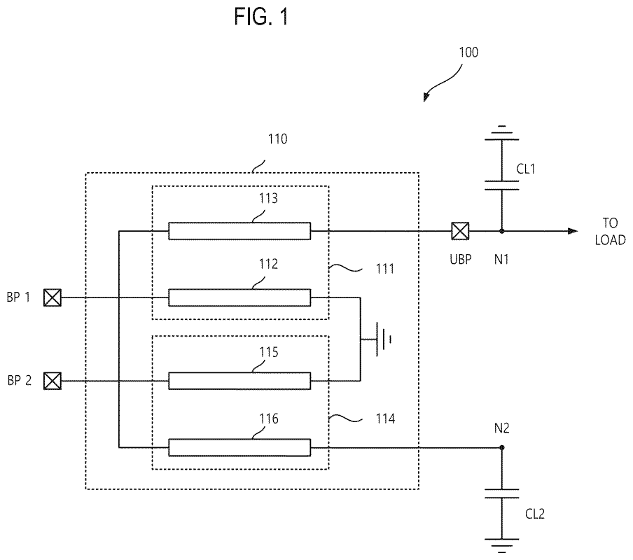

FIG. 1 is a circuit diagram of an output matching network, 100, according to an embodiment of the present disclosure. The output matching network 100 may include a pair of balanced ports BP1 and BP2, a balun circuit 110, an unbalanced port UBP, a first impedance matching capacitor CL1, and a second impedance matching capacitor CL2. The unbalanced port UBP may output a signal to a load.

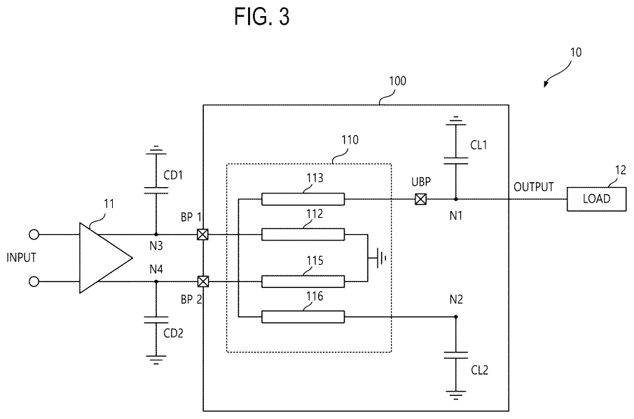

The pair of balanced ports BP1 and BP2 may be referred to as differential ports, and may receive differential signals of a differential signal pair, having different phases/polarities. For example, the pair of balanced ports BP1 and BP2 may be connected to a pair of output terminals of a power amplifier (e.g., 11 in FIG. 3 discussed later) outputting a differential signal pair in which an input signal is amplified. For example, differential signals applied to the pair of balance ports BP1 and BP2 may have a phase difference of 180 degrees from each other. Explained another way, first and second differential signals with opposite polarities may be applied to the balanced ports BP1 and BP2, respectively, where the first and second differential signals may form a differential signal pair. The balun circuit 110 is connected to the pair of balanced ports BP1 and BP2, and thus the differential signals may be input to the balun circuit 110.

The balun circuit 110 includes a first coupler 111 and a second coupler 114. The first coupler 111 and the second coupler 114 may convert differential signals input through the pair of balanced ports BP1 and BP2 into a single output signal and may output the single output signal to the unbalanced port UBP. The unbalanced port UBP may be a port of an unbalanced transmission line of the load, such as a port connecting to a signal conductor of a microstrip transmission line or a coplanar waveguide transmission line of an RF front-end component, e.g., a combiner, or an antenna feed line connecting to an antenna.

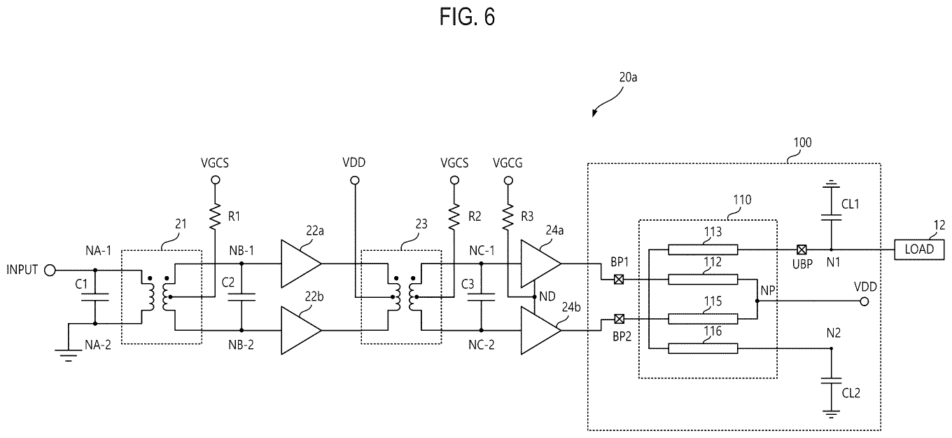

The first coupler 111 includes a first transmission line 112 and a third transmission line 113, which may be electromagnetically coupled to each other. A first end of the first transmission line 112 is connected to balanced port BP1 and a second end is connected to a circuit node of reference potential, e.g., ground as illustrated in FIG. 1, or alternatively a node at which a DC voltage is applied (e.g., VDD as shown in FIG. 6 discussed later). A first end of the third transmission line 113 is connected to the unbalanced port UBP, and a second end thereof is connected to a fourth transmission line 116.

The second coupler 114 includes the fourth transmission line 116 and a second transmission line 115, which may be electromagnetically coupled to each other. A first end of the second transmission line 115 is connected to the balanced port BP2, and a second end is connected to the circuit node of reference potential (e.g., ground or VDD). A first end of the fourth transmission line 116 is connected to the capacitor CL2 (at a node N2), and a second end is connected to a second end of the third transmission line 113.

The balun circuit 110 has a primary side and a secondary side. The primary side may be defined as including transmission lines 112 and 115, and the secondary side may be defined as including transmission lines 113 and 116. The primary side and the secondary side may be electromagnetically coupled to each other. Accordingly, the balun circuit 110 may operate with desired performance characteristics over a frequency domain after a Self Resonance Frequency (SRF). The pair of balanced ports BP1 and BP2 are connected to the primary side, and the unbalanced port UBP and the node N2 are connected to the secondary side. Accordingly, the differential signals input to the primary side may be converted into the single output signal which may be output through the secondary side.

Capacitors CL1 and CL2 are coupled to the secondary side of the balun circuit 110. Capacitor CL1 may be connected between a first node Ni (which may be understood as a circuit node of the unbalanced port UBP) and ground. The first node N1 is connected to the load. Capacitor CL2 is connected between the second node N2 (a node at the first end of transmission line 116) and ground.

In an embodiment, capacitances of the first and second capacitors CL1 and CL2 are different, such that the first and second capacitors CL1 and CL2 are considered asymmetric. As the first and second capacitors CL1 and CL2 are configured asymmetrically, the output matching network 100 may perform a function of matching an input impedance of an upper network including the output matching network 100 to a target optimal impedance. For instance, when the first and second capacitors CL1 and CL2 are asymmetric, the function of the output matching network 100 described above may be applied over a wide frequency range, and thus broadband characteristics may be improved. In addition, since an electrical length of the balun circuit 110 may be reduced due to the asymmetric configuration of the first and second capacitors CL1 and CL2, the entire circuit may be miniaturized.

When the first capacitor CL1 and the second capacitor CL2, which are asymmetric with each other, are coupled to the secondary side of the balun circuit 110, each of the first through fourth transmission lines 112-116, which are included in the balun circuit 110 according to an embodiment, may be configured such that each electrical length is 90 degrees or less. According to embodiments, the electrical length may also be configured to a length of 40 degrees or less.

The electrical length of each transmission line included in the balun circuit 110 may be set in relation to a characteristic impedance. The first through fourth transmission lines 112-116 may each have a characteristic impedance of an odd-mode and a characteristic impedance of an even-mode as design parameters. The impedance matching of the output matching network 100 may be performed by first determining the characteristic impedance of the odd-mode and the characteristic impedance of the even-mode.

The characteristic impedance of the odd-mode and the characteristic impedance of the even-mode may be adjusted based on the above-described first and second capacitors CL1 and CL2. In this case, the characteristic impedance of the odd-mode and the characteristic impedance of the even-mode having values according to capacitors CL1 and CL2 may be designed for a short electrical length, e.g., where an electrical length of each transmission line is 90 degrees or less (i.e., a physical length of the transmission line is λ/4 or less).

In addition, the fourth transmission line 116 is not directly grounded or shorted, but is connected to one side of capacitor CL2, where the other side of capacitor CL2 is connected to ground. In this case, it may be possible to design the characteristic impedance of the odd-mode and the characteristic impedance of the even-mode even for a short electrical length of each transmission line, e.g., 90 degrees or less, as compared to a case where the fourth transmission line 116 is directly grounded or shorted. For example, as the fourth transmission line 116 is connected to capacitor CL2, it is possible to design the characteristic impedance even at an electrical length of 40 degrees or less.

The output matching network 100 according to the above-described embodiment enables optimal impedance matching even over a wide bandwidth, and thus, broadband characteristics may be improved. In particular, according to the present disclosure, since impedance matching capacitors configured asymmetrically are additionally connected to the secondary side of the balun circuit 110, and a portion of the secondary side of the balun circuit 110 is connected to the impedance matching capacitor CL2 that is shunted to ground, impedance matching is possible over a wide bandwidth while reducing the length of the transmission lines included in the balun circuit 110. Therefore, there is an advantage that the structure of the matching network is miniaturized.

Hereinafter, various embodiments of the balun circuit 110 included in FIG. 1 will be described.

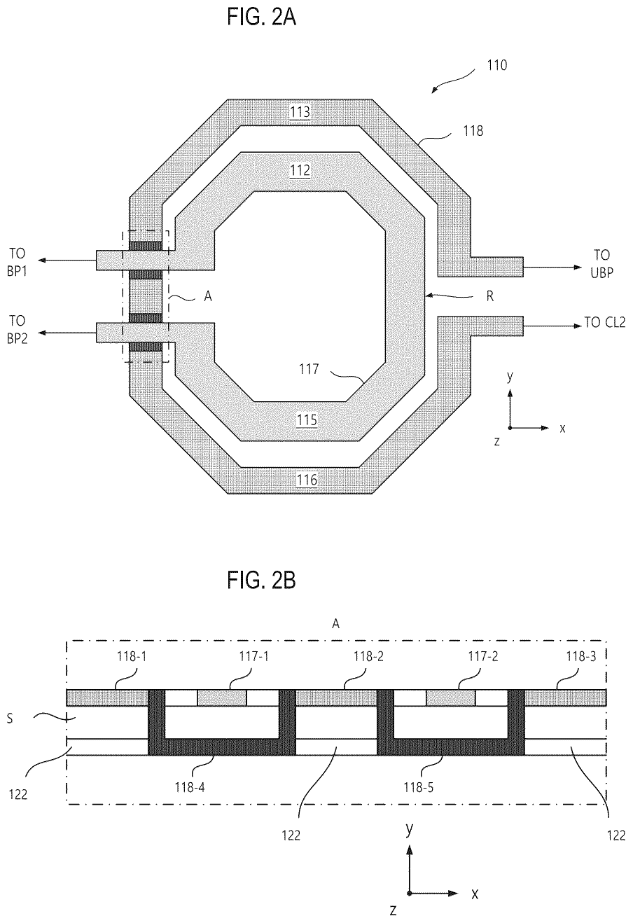

In an embodiment, in the balun circuit 110, the first coupler 111 and the second coupler 114 included in the balun circuit 110 are coupled in a broad-side form to each other, or an edge-side form to each other. In the present disclosure, the broad-side form may mean a structure in which a plurality of couplers are disposed parallel to each other along a vertical direction (e.g., the z direction in FIGS. 2A-2B), and the edge-side form may mean a structure in which a plurality of couplers are disposed parallel to each other along a horizontal direction (e.g., a direction in the x-y plane of FIGS. 2A-2B).

For example, when the balun circuit 110 has the broad-side form, the first transmission line 112 and the second transmission line 113 included in the balun circuit 110 may be disposed parallel to each other in the vertical direction and electromagnetically coupled, and the second transmission line 115 and the fourth transmission line 116 may be disposed parallel to each other in the vertical direction and electromagnetically coupled. In other words, the first coupler 111 and the second coupler 114 may each have portions located on different layers along the vertical direction.

For example, when the balun circuit 110 has the edge-side form, the first transmission line 112 and the second transmission line 113 included in the balun circuit 110 may be disposed parallel to each other in the horizontal direction and electromagnetically coupled, and the second transmission line 115 and the fourth transmission line 116 may be disposed parallel to each other in the horizontal direction and electromagnetically coupled. In other words, the first coupler 111 and the second coupler 114 may be located parallel to each other on the same horizontal plane.

FIG. 2A is a plan view of an edge-side type balun circuit, according to an embodiment of the present disclosure. In this example, the balun circuit 110 with the edge-side form includes a primary side 117 and a secondary side 118. The primary side 117 and the secondary side 118 may also be referred to as a primary side 117 winding and a secondary side 118 winding, respectively.

The primary side 117 includes the first transmission line 112 and the second transmission line 115 of FIG. 1. Thus, primary side 117 is connected to the pair of balance ports BP1 and BP2. The secondary side 118 includes the second transmission line 113 and the fourth transmission line 116. Accordingly, the secondary side 118 is connected to the unbalanced port UBP and the second capacitor CL2. As illustrated, the primary side 117 and a majority of the secondary side 118 are spaced parallel to each other on the same plane. Therefore, the primary side 117 and the secondary side 118 are electromagnetically coupled to each other to perform a role as a balun.

A portion of the primary side 117 may overlap a portion of the secondary side 118. For example, an area ‘A’ in which the primary side 117 is connected to the pair of balanced ports BP1 and BP2 as illustrated, may be an area in which the primary side 117 and the secondary side 118 overlap each other. In an embodiment, in the area ‘A’, the primary side 117 and the secondary side 118 may be configured to be located on different planes.

FIG. 2B is an example side view of an area ‘A’ of a balun circuit of FIG. 2A. An area 117-1 and an area 117-2 included in the area ‘A’ on the primary side 117 are connected to the pair of balance ports BP1 and BP2, and areas 118-1, 118-2, and 118-3 included in the area ‘A’ on the secondary side 118 are mutually located on the same plane and the same layer. The areas 117-1, 117-2, 118-1, 118-2, and 118-3 are disposed parallel to each other at a specified interval.

A U-shaped interconnecting conductor 118-4 included in the area ‘A’ on the secondary side 118 and connected to the area 118-1 and the area 118-2 overlaps with the area 117-1 of the primary side 117 on a horizontal plane, but does not overlap and may be spaced apart from each other on the side surface thereof. Another U-shaped interconnecting conductor 118-5 included in the area ‘A’ on the secondary side 118 and connected to the area 118-2 and the area 118-3 overlaps with the area 117-2 of the primary side 117 on a horizontal plane, but does not overlap and may be spaced apart from each other on the side surface thereof. Thus, the primary side 117 and the secondary side 118 may not physically overlap on a horizontal plane in the area A.

Comparing the example of FIGS. 2A-2B to the schematic diagram of FIG. 1, the first and second transmission lines 112 and 115 may be portions of the primary side 117 which is in the form of a continuous conductive trace arranged in an open loop configuration. The “open” part of the open loop is at the area A. The first and second transmission lines 112 and 115 may be considered connected at a central region R of the open loop configuration. The first transmission line 112 may correspond to approximately one half of the open loop configuration and the second transmission line 115 may correspond to a remaining portion, which is approximately one half of the open loop configuration. The central region R may be connected to a node of reference potential, e.g., ground or a node receiving VDD.

Likewise, the third and fourth transmission lines 113 and 116 may be portions of the secondary side 118 which is also in the form of a continuous conductive trace, arranged in a second open loop configuration. The “open” portion of the second open loop is at the region of the connections to the unbalanced port UBP and the second capacitor CL2. The third and fourth transmission lines 113 and 116 may be considered connected at the area A. The third transmission line 113 may correspond to approximately one half of the second open loop configuration and the second transmission line 115 may correspond to the remaining, approximately one half of the second open loop configuration.

The balun circuit 110 may be configured to electromagnetically couple transmission lines according to various forms other than the broad-side form or the edge-side form according to the above-described embodiments.

FIG. 3 is a circuit diagram of a power amplifier network, 10, according to an embodiment of the present disclosure. The power amplifier network 10 additionally includes a power amplifier 11 connected to input terminals of the above-described output matching network 100. The power amplifier network 10 may drive a load 12.

The power amplifier 11 is configured to amplify an input signal which is a differential signal pair including first and second differential signals, and to output an output signal which is a differential signal pair as well. The output matching network 100 is connected to output terminals of the power amplifier 11, and an input impedance defined at the output terminals of the power amplifier 11 may be matched as an optimal impedance based on the output matching network 100. Accordingly, the power amplifier 11 may have maximum output power and high power efficiency through the provision of the output matching network 100.

The load 12 is connected to an output terminal (node N1) of the output matching network 100 and receives an output signal amplified from the input signal. The load 12 may receive an output signal converted into a single output signal (non-differential) through the output matching network 100.

The output matching network 100 is provided between the power amplifier 11 and the load 12. The output matching network 100 converts output signals of the power amplifier 11, which are differential signals, into the single output signal and provides the single output signal to the load 12. In this case, the output matching network 100 includes the pair of balanced ports BP1 and BP2, the balun circuit 110, the unbalanced port UBP, the first capacitor CL1, and the second capacitor CL2.

The balun circuit 110 has an input side connected to the pair of balanced ports BP1 and BP2, and an output side connected to the unbalanced port UBP and the capacitor CL2. The transmission line 113 included in the balun circuit 110 is connected to the unbalanced port UBP, and the fourth transmission line 116 is connected to the capacitor CL2. Accordingly, even if the first through fourth transmission lines 112-116 each have an electrical length of 90 degrees or less, optimal impedance matching may be possible. In addition, since the first capacitor CL1 and the second capacitor CL2 are configured asymmetrically, optimum impedance matching may be possible over a wide bandwidth.

In an embodiment, the power amplifier network 10 further includes a pair of input capacitors CD1 and CD2 connected to the pair of balance ports BP1 and BP2, respectively. Capacitor CD1 is connected to a third node N3 connected to a first output terminal of the power amplifier 11 and the first balance port BP1. Capacitor CD2 is connected to a fourth node N4 connected to a second output terminal of the power amplifier 11 and the second balanced port BP2. The pair of input capacitors CD1 and CD2 may be designed such that the input impedance defined at an input terminals of the power amplifier network 10 matches the optimum impedance of the amplifier 11. To this end, the pair of input capacitors CD1 and CD2 may be designed to minimize an imaginary component of input impedance. The characteristic impedance of the transmission lines included in the balun circuit 110 may be designed depending on the capacitance value of the pair of input capacitors CD1 and CD2.

For example, the characteristic impedance of the odd-mode and the characteristic impedance of the even-mode may also be adjusted through the pair of input capacitors CD1 and CD2 in addition to the above-described first and second impedance matching capacitors CL1 and CL2.

In another embodiment, the above-described pair of input capacitors CD1 and CD2 may be parasitic capacitors of the power amplifier 11. In this case, the configuration of the circuit is possible without an additional capacitor element.

The power amplifier network 10 according to the above-described embodiment may achieve optimal impedance matching over a wide bandwidth, and thus may have improved wide band characteristics through the output matching network 100 in which the capacitors CL1 and CL2 configured asymmetrically with each other are additionally connected to the secondary side 118 of the balun circuit 110. In particular, since a portion of the secondary side 118 of the balun circuit 110 is connected to the capacitor CL2, it is possible to miniaturize the entire network. In addition, optimum impedance matching is possible through use of the pair of input capacitors CD1 and CD2 and the balun circuit 110, and additional elements are not required when the parasitic capacitor of the power amplifier 11 is used according to an embodiment.

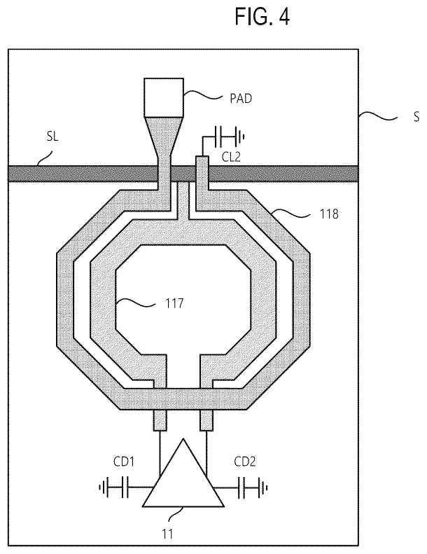

FIG. 4 is a diagram illustrating an integrated circuit of a power amplifier network of FIG. 3. In this example, the power amplifier network 10 integrated on a substrate S′. As described above, the primary side 117 of the balun circuit 110 is connected to the output terminals of the power amplifier 11. The pair of input capacitors CD1 and CD2 are connected to the differential output terminals of the power amplifier 11. Here, capacitors CD1 and CD2 may be implemented as parasitic capacitors of the power amplifier 11.

A supply line SL for providing a driving voltage may be connected to the primary side 117 of the balun circuit 110. A pad PAD may be connected to the secondary side 118 of the balun circuit 110 and serve as a transition to the load 12.

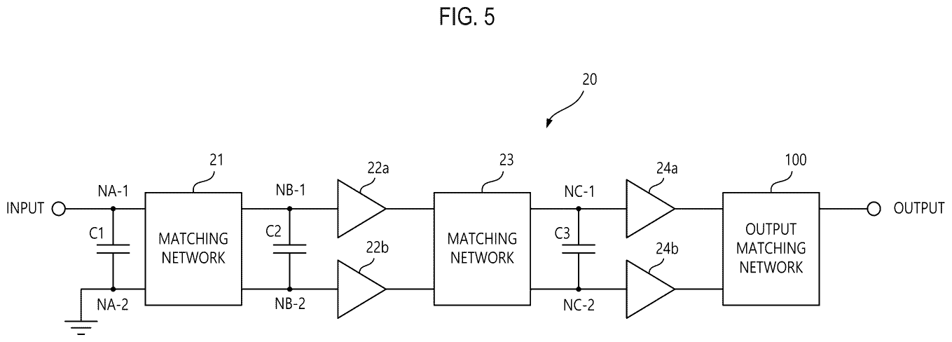

FIG. 5 is a circuit diagram of a power amplifier network, 20, according to another embodiment of the present disclosure. A circuit of the power amplifier network 20 includes a first matching network 21, a pair of drive amplifiers 22a and 22b, a second matching network 23, a pair of power amplifiers 24a and 24b, and the output matching network 100.

The first matching network 21 is provided between an input terminal pair and the pair of drive amplifiers 22a and 22b for impedance matching of the power amplifier network 20. An input signal is applied to an input node NA-1 of the input terminal pair, and an input node NA-2 of the input terminal pair is grounded. The input signal may be a Radio Frequency (RF) signal. A capacitor Cl is connected between the input nodes NA-1 and NA-2.

The pair of drive amplifiers 22a and 22b are provided between an output terminal pair of the first matching network 21 and an input terminal pair of the second matching network 23. The pair of drive amplifiers 22a and 22b adjust a gain of the signal before an amplification step through the power amplifiers 24a and 24b. The pair of drive amplifiers 22a and 22b may improve linear performance and power efficiency through matching between stages with the power amplifiers 24a and 24b through the first matching network 21 and the second matching network 23.

Input terminals of the pair of drive amplifiers 22a and 22b are connected to a node NB-1 and a node NB-2 connected to the output terminal of the first matching network 21. A capacitor C2 is connected between the nodes NB-1 and NB-2.

The second matching network 23 is provided between the pair of drive amplifiers 22a and 22b and the pair of power amplifiers 24a and 24b for impedance matching of the power amplifier network 20. The pair of power amplifiers 24a and 24b are connected to a node NC-1 and a node NC-2 at an output terminal pair of the second matching network 23. A capacitor C3 is connected between the nodes NC-1 and NC-2.

The pair of power amplifiers 24a and 24b amplify the input signal of which the gain is adjusted from the pair of drive amplifiers 22a and 22b, and transfer the amplified signal to the output matching network 100.

The output matching network 100 is provided for output impedance matching of the power amplifier network 20 according to the above-described embodiments. In an embodiment, when the input/output signal of each amplifier is a differential signal pair composed of two differential signals, the output matching network 100 converts the two differential signals, which are signals amplified by the power amplifiers 24a and 24b, into a single signal and outputs the converted signal. As described above, an input side of the output matching network 100 is connected to the balanced ports BP1 and BP2 and an output side is connected to a load and the capacitor CL2 (not shown in FIG. 5). Accordingly, the power amplifier network 20 may have maximum output power and high power efficiency since impedance matching is possible over a wide bandwidth.

FIG. 6 is a circuit diagram of an embodiment, 20a, of the power amplifier network 20 of FIG. 5. The input side of the first matching network 21 included in power amplifier network 20a includes the input nodes NA-1 and NA-2, and the capacitor C1 connected across the input nodes. The input signal passes through the first matching network 21 through the input side. A gain of the passed input signal is adjusted through the pair of drive amplifiers 22a and 22b, and the gain-adjusted input signal is transferred to the second matching network 23. An input terminal pair of the second matching network 23 includes the nodes NB-1 and NB-2. The capacitor C2 is connected across nodes NB-1 and NB-2.

For example, the first matching network 21 and the second matching network 23 may use a transformer-based high-order filter. A voltage VGCS is applied to the secondary side of the first matching network 21 through a first resistor R1. In this case, the voltage VGCS is a biasing gate voltage of the pair of drive amplifiers 22a and 22b. A voltage VDD is applied to the primary side of the second matching network 23, and the voltage VGCS is applied to the secondary side of the second matching network 23 through a second resistor R2. In this case, the voltage VDD is the driving voltage of the pair of drive amplifiers 22a and 22b, and the voltage VGCS is the biasing gate voltage of the pair of power amplifiers 24a and 24b.

Although the transformer-based network is illustrated as an example of the first matching network 21 and the second matching network 23 in FIG. 6, various other matching networks (e.g., shunt inductor based, L-network based, etc.) capable of serving as inter-stage matching networks may be alternatively used.

The gain-adjusted input signal passes through the second matching network 23 and is applied to the pair of power amplifiers 24a and 24b. The pair of power amplifiers 24a and 24b amplify the input signal and transfer the amplified signal to the output matching network 100. A voltage VGCG is applied to a node ND connected to the pair of power amplifiers 24a and 24b through a third resistor R3. In this case, the voltage VGCG is the biasing gate voltage of the pair of power amplifiers 24a and 24b. The voltages VGCG and VGCS may be biasing gate voltages for different transistors.

The output matching network 100 converts the amplified signal applied through the pair of balanced ports BP1 and BP2 through the balun circuit 110 from differential signals to a single signal and outputs the converted signal to the unbalanced port UBP. The converted single signal is finally transferred to the load 12. The fourth transmission line 116 of the balun circuit 110 is connected to the capacitor CL2 at the second node N2. The first capacitor CL1 connected to the unbalanced port UBP and the second capacitor CL2 connected to the node N2 may be configured asymmetrically. Therefore, the output matching network 100 may improve broadband characteristics while reducing the length of the transmission lines included in the balun circuit 110.

The other ends of the first transmission line 112 and the second transmission line 115 included in the balun circuit 110 may be grounded or connected to a node NP as illustrated. That is, the other ends of the first transmission line 112 and the second transmission line 115 may be AC grounded. In the latter case, the voltage VDD may be applied to the node NP where VDD is the driving voltage of the pair of power amplifiers 24a and 24b.

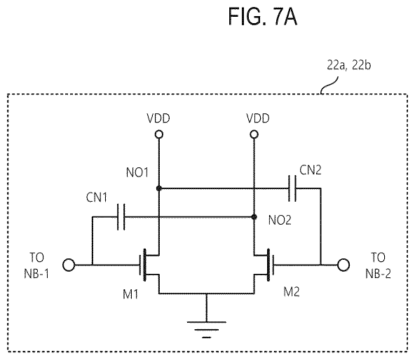

FIG. 7A and 7B are respective example circuit diagrams of a drive amplifier and a power amplifier of FIG. 6.

Referring to FIG. 7A, for example, each of the pair of drive amplifiers 22a and 22b includes a first transistor Ml, a second transistor M2, a first neutral capacitor CN1, and a second neutral capacitor CN2. The first transistor M1 and the second transistor M2 are biased by the aforementioned voltage VGCS. The first transistor M1 and the second transistor M2 may operate depending on input signals applied through the nodes NB-1 and NB-2. An output signal of which the gain is adjusted is output through a first output node NO1 and a second output node NO2 connected to the first transistor M1 and the second transistor M2. The first neutral capacitor CN1 is connected between the node NB-1 and the second output node NO2, and the second neutral capacitor CN2 is connected between the node NB-2 and the first output node NO1. A reverse blocking function of the pair of drive amplifiers 22a and 22b may be provided through the first neutral capacitor CN1 and the second neutral capacitor CN2.

Referring to FIG. 7B, for example, each of the pair of power amplifiers 24a and 24b includes a third transistor M3, a fourth transistor M4, a third neutral capacitor CN3, a fourth neutral capacitor CN4, a fifth transistor M5, and a sixth transistor M6. The third transistor M3 and the fourth transistor M4 are biased by the aforementioned voltage VGCS. The third transistor M3 and the fourth transistor M4 may operate depending on input signals applied through the node NC-1 and the node NC-2. An output signal of which the gain is adjusted is output through a third output node NO3 and a fourth output node NO4 connected to the third transistor M3 and the fourth transistor M4. The third neutral capacitor CN3 is connected between the node NC-1 and the fourth output node NO4, and the fourth neutral capacitor CN4 is connected between the node NC-2 and the third output node NO3. A reverse blocking function of the pair of power amplifiers 24a and 24b may be provided through the third neutral capacitor CN3 and the fourth neutral capacitor CN4.

In addition, the fifth transistor M5 is connected to the third output node NO3 and the sixth transistor M6 is connected to the fourth output node NO4. The fifth transistor M5 and the sixth transistor M6 may operate depending on the voltage VGCG.

The pair of drive amplifiers 22a and 22b and the pair of power amplifiers 24a and 24b according to FIGS. 7A and 7B are merely examples, are not limited thereto, and may be configured in various other ways to perform a gain control function and a power amplification function.

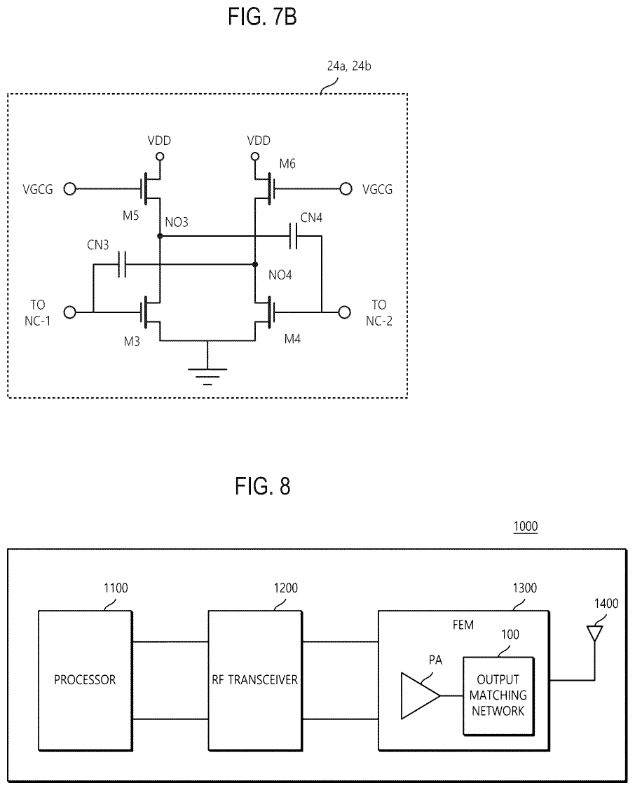

FIG. 8 illustrates a wireless communication device, 1000, according to an embodiment of the present disclosure. The wireless communication device 1000 includes a processor 1100, an RF transceiver 1200, front end circuitry (interchangeably, “front-end module (FEM))” 1300, and an antenna 1400.

The processor 1100 may modulate various digital data to generate digital signals and may provide the generated digital signals to the RF transceiver 1200. Alternatively or additionally, the processor 1100 may demodulate digital signals received from the RF transceiver 1200 and may restore original digital data. The processor 1100 may be a modem.

The RF transceiver 1200 may convert a digital signal transmitted from the processor 1100 into an RF signal of an RF frequency band or may convert an RF signal received by and routed from the antenna 1400 into a baseband digital signal. For example, the RF transceiver 1200 may generate a broadband RF signal of 20 GHz or higher.

The FEM 1300 converts and amplifies the RF signal received from the RF transceiver 1200 into an analog signal and transmits it to the antenna 1400, or low-noise amplifies the RF signal received from the antenna 1400 and provides it to the RF transceiver 1200.

In an embodiment, the FEM 1300 includes a power amplifier PA and the output matching network 100. The power amplifier PA amplifies the RF signal received from the RF transceiver 1200 and transfers it to the output matching network 100. The output matching network 100 may match an input impedance defined at an input terminal of the power amplifier PA to the optimal impedance.

The output matching network 100 may be implemented according to various embodiments described above. In an embodiment, the output matching network 100 may include the balun circuit 110, where a portion of the secondary side 118 of the balun circuit 110 is connected to the balanced ports BP1 and BP2 leading to the antenna 1400, while another portion is connected to the capacitor CL2. The first capacitor CL1 and the second capacitor CL2 may be provided on the secondary side 118 of the balun circuit 110. Therefore, the FEM 1300 may output an RF signal to the antenna 1400 with maximum output power and high power efficiency over a wide bandwidth.

The antenna 1400 may transmit the RF analog signal received from the FEM 1300 to another wireless communication device or base station (not shown), and/or may transfer the RF analog signal received from the other wireless communication device or base station to the FEM 1300. The antenna 1400 may be configured to support technologies such as beamforming and multiple-input and multiple-output (MIMO).

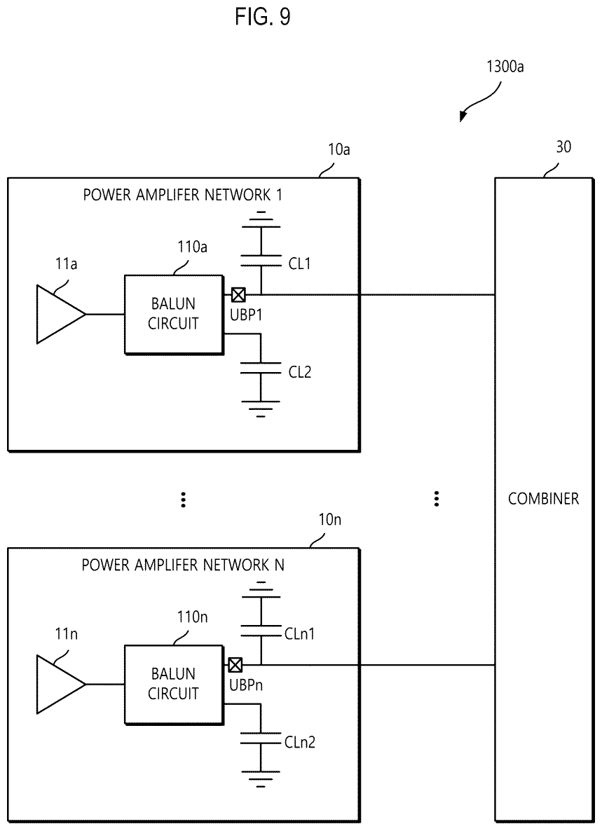

FIG. 9 is a diagram illustrating another embodiment of an FEM, 1300a, that may be substituted for the FEM 1300 of FIG. 8. The FEM 1300a may include a plurality of power amplifier networks 10a to 10n and a combiner 30 connected to the plurality of power amplifier networks 10a to 10n. The plurality of power amplifier networks 10a to 10n respectfully include power amplifiers 11a to 11n, balun circuits 110a to 110n, and the first capacitor CL1 and the second capacitor CL2 respectively connected to output terminals of the balun circuits 110a to 110n, according to the above-described embodiments. Each of the plurality of power amplifier networks 10a to 10n provides an output signal amplified by the power amplifiers 11a to 11n to the combiner 30. Based on the fact that the first capacitor CL1 and the second capacitor CL2 configured asymmetrically with each other and a portion of the secondary sides 118 of the balun circuits 110a to 110n are connected to the capacitor CL2, the impedance matching of each of the power amplifier networks 10a to 10n may be performed, and thus may amplify a signal with maximum output power and high power efficiency over a wide bandwidth.

The combiner 30 is configured to combine the amplified output signals from each of the plurality of power amplifier networks 10a to 10n to generate one RF signal. An input terminal of the combiner 30 is applied with an amplified RF signal output through the balance ports BP1 and BP2 of each of the plurality of power amplifier networks 10a to 10n. The combiner 30 may amplify power of a signal to be transferred to the antenna 1400 by combining all received RF signals into one RF signal. The combiner 30, and/or the combiner 30 together with an antenna (not shown) connected to the output of the combiner 30, is an example of the above-mentioned load 12.

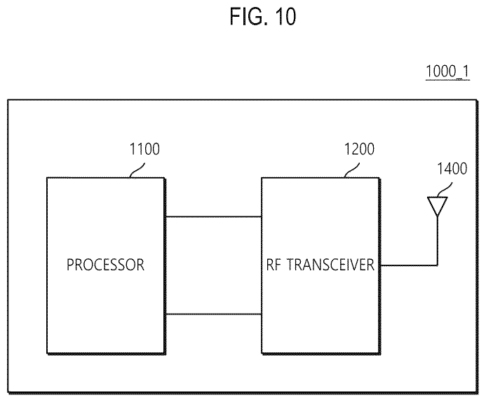

FIG. 10 illustrates a wireless communication device, according to another embodiment of the present disclosure. Hereinafter, a detailed description of the overlapping portion with FIG. 9 will be omitted to avoid redundancy.

Referring to FIG. 10, a wireless communication device 1000_1 according to another embodiment includes the processor 1100, the RF transceiver 1200, and the antenna 1400. Unlike FIG. 8, the above-described FEM may be integrated into the RF transceiver 1200 of the wireless communication device 1000_1.

The processor 1100 may provide a signal to the RF transceiver 1200 and/or may demodulate a signal received from the RF transceiver 1200.

The RF transceiver 1200 may convert a baseband signal into an RF signal, may convert and amplify the converted RF signal into an analog signal, and may transfer the amplified RF signal to the antenna 1400. Alternatively or additionally, the RF transceiver 1200 may amplify and convert the RF signal received from the antenna 1400 into a low-noise signal.

As an embodiment, the RF transceiver 1200 may include the power amplifier PA and the output matching network 100 according to the above-described embodiments. The power amplifier PA may amplify the RF signal and may transfer the amplified RF signal to the output matching network 100, and the output matching network 100 may match an input impedance defined at an input terminal of the power amplifier PA to the optimal impedance. The antenna 1400 is an example of the above-mentioned load 12.

The output matching network 100 may be implemented according to various embodiments described above. In an embodiment, the output matching network 100 may include the balun circuit 110, a portion of the secondary side 118 of the balun circuit 110 is connected to the balanced ports BP1 and BP2 leading to the antenna 1400, while another portion is connected to the capacitor CL2. The first capacitor CL1 and the second capacitor CL2 may be provided on the secondary side 118 of the balun circuit 110. Therefore, the RF transceiver 1200 may output an RF signal to the antenna 1400 with maximum output power and high power efficiency even over a wide frequency band.

According to an embodiment of the present disclosure, an output matching network with improved wide frequency band characteristics through a balun circuit that may be configured with transmission lines having shorter lengths relative to prior art designs, and a power amplifier network including the same may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An output matching network comprising:
a first transmission line and a second transmission line each having one end connected to a respective balanced port of a pair of balanced ports;
a third transmission line having one end connected to an unbalanced port;
a fourth transmission line;
a first capacitor connected to the unbalanced port and a load; and
a second capacitor connected to an end of the fourth transmission line,
wherein the third and fourth transmission lines are coupled to the first and second transmission lines.

2. The output matching network of claim 1, wherein a capacitance of the first capacitor differs from a capacitance of the second capacitor.

3. The output matching network of claim 1, wherein each of the first through fourth transmission lines has an electrical length of 90 degrees or less.

4. The output matching network of claim 1, wherein the first and third transmission lines are electromagnetically coupled to one another, and are disposed parallel to each other in a horizontal or vertical direction, and
the second and fourth transmission lines are electromagnetically coupled to one another and are disposed parallel to each other in a horizontal or vertical direction.

5. The output matching network of claim 1, further comprising:
a pair of input capacitors connected to the pair of balanced ports.

6. The output matching network of claim 1, wherein an odd-mode characteristic impedance and an even-mode characteristic impedance of each of the first through fourth transmission lines are adjusted based on the first and second capacitors.

7. The output matching network of claim 1, wherein another end of each of the first and second transmission lines is grounded.

8. The output matching network of claim 1, wherein another end of the first transmission line is connected to another end of the second transmission line.

9. A power amplifier network comprising:
a power amplifier configured to amplify an input signal to provide an amplified input signal including first and second differential signals, at first and second balanced ports, respectively; and
an output matching network including:
an unbalanced port at which an unbalanced output signal is output to a load;
a balun circuit including a plurality of transmission lines that receive the first and second differential signals, wherein the balun circuit converts the first and second differential signals to the unbalanced output signal at the unbalanced port;
a first capacitor connected to the unbalanced port; and
a second capacitor connected between an end of one of the transmission lines and a circuit node of reference potential.

10. The power amplifier network of claim 9, wherein the one of the transmission lines is a fourth transmission line, and the balun circuit further includes:
a first transmission line having one end connected to the first balanced port;
a second transmission line having one end connected to the second balanced port; and
a third transmission line having one end connected to the unbalanced port.

11. The power amplifier network of claim 9, wherein a capacitance of the first capacitor differs from a capacitance of the second capacitor.

12. The power amplifier network of claim 10, wherein the first through fourth transmission lines each have an electrical length of 90 degrees or less.

13. The power amplifier network of claim 10, wherein the first and third transmission lines are electromagnetically coupled to one another and disposed parallel to each other in a horizontal or vertical direction, and
the second and fourth transmission lines are electromagnetically coupled to one another and disposed parallel to each other in a horizontal or vertical direction.

14. The power amplifier network of claim 9, further comprising:
a pair of input capacitors connected to the first and second balanced ports.

15. The power amplifier network of claim 10, wherein an odd-mode characteristic impedance and an even-mode characteristic impedance of each of the first through fourth transmission lines are adjusted based on the first and second capacitors.

16. A wireless communication device comprising:
a processor;
a radio frequency (RF) transceiver configured to convert a digital signal generated by the processor into an RF signal;
front end circuitry; and
an antenna,
wherein the front end circuitry includes:
a power amplifier configured to amplify the RF signal to provide an amplified RF signal including first and second differential signals at first and second balanced ports, respectively; and
an output matching network including:
an unbalanced port at which an unbalanced output signal is output to a load;
a balun circuit including a plurality of transmission lines that receive the first and second differential signals, wherein the balun circuit converts the first and second differential signals to the unbalanced output signal at the unbalanced port;
a first capacitor connected to the unbalanced port; and
a second capacitor connected between an end of one of the transmission lines and a point of reference potential,
wherein the antenna is configured to transmit the unbalanced output signal.

17. The wireless communication device of claim 16, wherein the one of the transmission lines is a fourth transmission line, and the balun circuit further includes:
a first transmission line having one end connected to the first balanced port;
a second transmission line having one end connected to the second balanced port; and
a third transmission line having one end connected to the unbalanced port.

18. The wireless communication device of claim 16, wherein the load includes the antenna.

19. The wireless communication device of claim 16, wherein a capacitance of the first capacitor differs from a capacitance of the second capacitor.

20. The wireless communication device of claim 17, wherein the first through fourth transmission lines each have an electrical length of 90 degrees or less.
